(19) United States
(12) Patent Application Publication
(10) Pub. No.: US 2025/0389010 A1
(43) Pub. Date: Dec. 25, 2025

(54) MASK ASSEMBLY AND DEPOSITION DEVICE INCLUDING THE SAME

(71) Applicant: SAMSUNG DISPLAY CO., LTD., Yongin-si (KR)

(72) Inventors: YOUNGSUN CHO, Yongin-si (KR); JONGBUM KIM, Yongin-si (KR); JONGSUNG PARK, Yongin-si (KR); Mina WOO, Yongin-si (KR); Gyeongseon YOO, Yongin-si (KR)

(21) Appl. No.: 19/219,148

(22) Filed: May 27, 2025

(30) Foreign Application Priority Data
Jun. 25, 2024 (KR) 10-2024-0083187
Aug. 14, 2024 (KR) 10-2024-0109391

(51) Int. Cl. C23C 14/04

(52) U.S. Cl. CPC C23C 14/042

(57) ABSTRACT

A mask assembly and a deposition device including the same are disclosed. A mask assembly includes: a mask frame, a first mask bar connected to the mask frame and extending in a first direction, and a second mask bar connected to the mask frame and extending in a second direction. The first mask bar overlaps the second mask bar in an overlapping region, the second mask bar includes a non-overlapping region not overlapping the first mask bar, the second mask bar includes a first portion having a first thickness and a second portion having a second thickness that is less than the first thickness in the non-overlapping region, and the first portion is located along an edge of the second mask bar.

### CROSS-REFERENCE TO RELATED APPLICATION

The present application claims priority to and the benefit of Korean Patent Application No. 10-2024-0109391, filed on Aug. 14, 2024, in the Korean Intellectual Property Office, and Korean Patent Application No. 10-2024-0083187, filed on Jun. 25, 2024, in the Korean Intellectual Property Office, the entire disclosures of both of which are incorporated herein by reference.

### BACKGROUND

### 1. Field

Aspects of embodiments of the present disclosure relate to a mask assembly and a deposition device including the same.

### 2. Description of the Related Art

A display device includes any of a liquid crystal display (LCD), a plasma display panel (PDP), an organic light emitting diode (OLED) device, a field emission display (FED), and an electrophoretic display device, for example.

Many layers included in the display device may be formed using a mask with openings defined by a blocking portion.

If the blocking portion of the mask lifts depending on a position, a thin film may be stacked on unnecessary positions during a manufacturing process.

### SUMMARY

According to an aspect of embodiments of the present disclosure, a mask assembly having increased accuracy of a deposition process, and a deposition device including the same, are provided.

However, aspects and objects of the present disclosure are not limited to the above-described aspects and objects, and may be expanded in various ways in the range of the ideas and the areas of the present disclosure.

According to one or more embodiments of the present disclosure, a mask assembly includes: a mask frame; a first mask bar connected to the mask frame and extending in a first direction; and a second mask bar connected to the mask frame and extending in a second direction. The first mask bar may overlap the second mask bar in an overlapping region, the second mask bar may include a non-overlapping region not overlapping the first mask bar, the second mask bar may include a first portion having a first thickness and a second portion having a second thickness that is less than the first thickness in the non-overlapping region, and the first portion may be along an edge of the second mask bar.

The first portion may include two first sub-portions located at edges at opposite sides of the second mask bar in the first direction and spaced apart from each other, and the second portion may be between the two first sub-portions.

The second mask bar may include a dummy groove corresponding to the second portion.

The second mask bar may be on the first mask bar in the overlapping region.

The dummy groove may be at a bottom surface of the second mask bar.

The dummy groove may include a first dummy groove at a bottom surface of the second mask bar, and a second dummy groove at an upper surface of the second mask bar.

The second mask bar may include a combination groove corresponding to the overlapping region.

A depth of the dummy groove may be the same (equal or substantially equal) to a depth of the combination groove.

The first sub-portions may extend in parallel to the second direction, and the second portion may extend in parallel to the second direction.

A length of the second portion may be the same (equal or substantially equal) to a length of the non-overlapping region in a parallel direction to the second direction.

The first portion may further include second sub-portions extending in the second direction and connecting the first sub-portions.

The dummy groove may include grooves surrounded by the first sub-portions and the second sub-portions.

A length of each of the second sub-portions may be less than a length of the dummy groove in the second direction.

A length of each of the second sub-portions may be the same (equal or substantially equal) to a length of the dummy groove in the second direction.

According to one or more embodiments of the present disclosure, a deposition device includes: a chamber providing a process region; a deposition member and a fixing member facing each other in the chamber; and a mask assembly between the deposition member and the fixing member, wherein a substrate to be processed may be between the fixing member and the mask assembly, the mask assembly may include a mask frame, a first mask bar connected to the mask frame and extending in the first direction, and a second mask bar connected to the mask frame and extending in the second direction, the first mask bar may overlap the second mask bar in the overlapping region, the second mask bar may include a non-overlapping region not overlapping the first mask bar, the second mask bar may include a first portion having a first thickness and a second portion having a second thickness that is less than the first thickness in the non-overlapping region, and the first portion may be along an edge of the second mask bar.

According to one or more embodiments, the mask assembly for increasing accuracy of the deposition process and the deposition device including the same are provided.

However, aspects and effects of the present disclosure are not limited to the above-described aspects and effects, and may be expanded in various ways without departing from the spirit and scope of the present disclosure.

### BRIEF DESCRIPTION OF THE DRAWINGS

FIG. 1 is a cross-sectional view of a deposition device according to an embodiment.

FIG. 2 is a top plan view of a mask assembly according to an embodiment.

FIG. 3 is an enlarged view of a region of FIG. 2.

FIG. 4 is an enlarged view of a portion of a mask assembly according to an embodiment.

FIG. 5 is a cross-sectional view along a line I-I′ of FIG. 3.

FIG. 6 is a cross-sectional view along a line II-II′ of FIG. 3.

FIG. 7 is a cross-sectional view along a line III-III′ of FIG. 3.

FIG. 8 is a top plan view illustrating a method for manufacturing a mask assembly according to an embodiment.

FIG. 9 and FIG. 10 are each a cross-sectional view of a portion of a mask assembly of a deposition device according to another embodiment.

FIG. 11 is a top plan view of a portion of a mask assembly of a deposition device according to another embodiment.

FIG. 12 is a top plan view of a portion of a mask assembly of a deposition device according to another embodiment.

FIG. 13 is a top plan view of a display panel according to an embodiment.

FIG. 14 is a cross-sectional view of a display panel according to an embodiment.

FIG. 15 is a block diagram of an electronic device according to an embodiment.

FIGS. 16 to 18 are schematic views of electronic devices according to some embodiments.

### DESCRIPTION OF SYMBOLS

100: deposition device
10: display panel
CHB: chamber
EP: deposition member
SCP: fixing member
SUB: substrate
MSKA: mask assembly
MFR: mask frame
MSK: mask
MPBA, MPBB: mask bar
DRA: opening region
OLP: overlapping portion
NOLP: non-overlapping portion
CPH, CPH1: combination groove
DMH, DMHA, DMHB: dummy groove
ED: end portion
T1, T2, T3, T4: thickness
D1, D2: depth
W1, W2: width
L1, L2, L3, L4: length

### DETAILED DESCRIPTION

The present disclosure will be described more fully herein with reference to the accompanying drawings, in which some embodiments of the disclosure are shown. As those skilled in the art will realize, the described embodiments may be modified in various different ways, without departing from the spirit or scope of the present disclosure.

Portions that are irrelevant to the description may be omitted to more clearly describe the present disclosure, and like elements will be designated by like reference numerals throughout the specification.

The accompanying drawings are provided to allow embodiments disclosed in the present specification to be easily understood but are not to be interpreted as limiting the spirit disclosed in the present specification, and it is to be understood that the present disclosure includes all modifications, equivalents, and substitutions without departing from the scope and spirit of the present disclosure.

The size and thickness of each configuration shown in the drawings may arbitrarily shown for better understanding and ease of description, but the present disclosure is not limited thereto. In the drawings, the thicknesses of layers, films, panels, regions, etc., may be enlarged for clarity. The thicknesses of some layers and areas may be exaggerated for convenience of explanation.

It is to be understood that when an element, such as a layer, film, region, or substrate, is referred to as being “on” another element, it may be directly on the other element or one or more intervening elements may also be present. By contrast, when an element is referred to as being “directly on” another element, there are no intervening elements present.

Unless explicitly described to the contrary, the word “comprise,” and variations such as “comprises” or “comprising,” is to be understood to imply the inclusion of stated elements but not the exclusion of other elements.

The phrase “in a plan view” means viewing an object portion from the top, and the phrase “in a cross-sectional view” means viewing a cross-section of which the object portion is perpendicularly cut from the side.

When it is stated that a portion is “connected” to another portion, the portion may be directly connected to the other portion, may be connected to the other portion through a third portion, or may be connected to the other portion physically or electrically, and they may be referred to by different names according to positions or functions, but portions that are substantially integrated into one body may be connected to each other.

Various embodiments and variations will now be described with reference to the accompanying drawings.

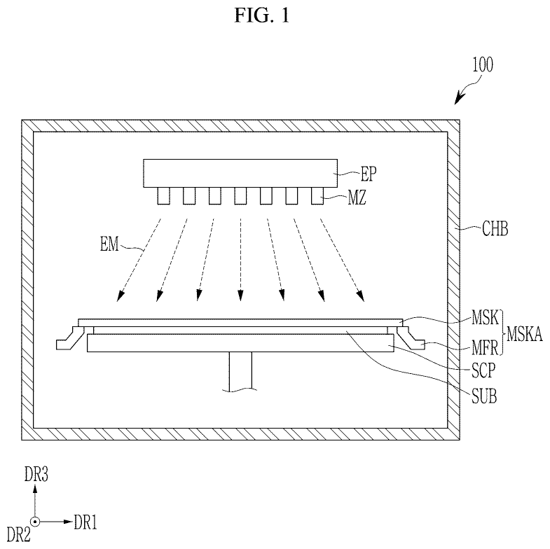

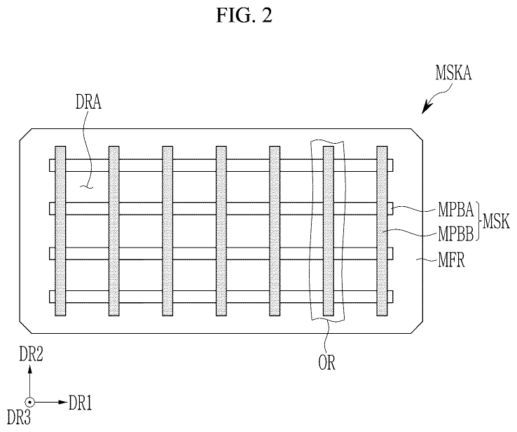

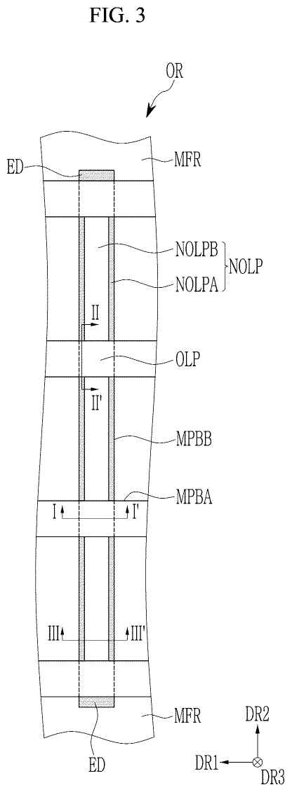

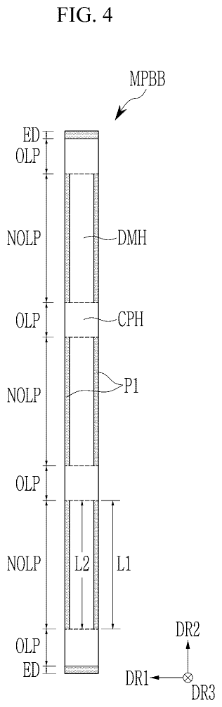

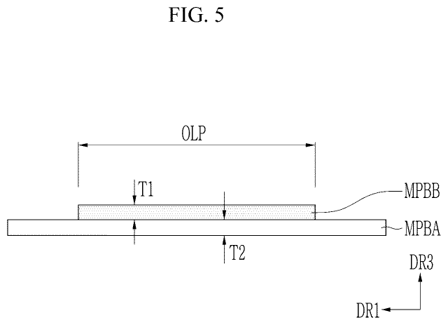

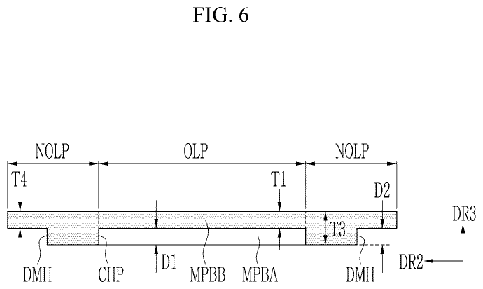

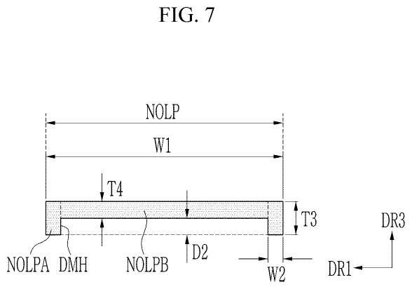

A deposition device 100 according to an embodiment will now be described with reference to FIG. 1 to FIG. 7. FIG. 1 is a cross-sectional view of a deposition device according to an embodiment; FIG. 2 is a top plan view of a mask assembly according to an embodiment; FIG. 3 is an enlarged view of a region of FIG. 2; FIG. 4 is an enlarged view of a portion of a mask assembly; FIG. 5 is a cross-sectional view along a line I-I′ of FIG. 3; FIG. 6 is a cross-sectional view along a line II-II′ of FIG. 3; and FIG. 7 is a cross-sectional view along a line III-III′ of FIG. 3. FIG. 3 shows a bottom surface of a region (e.g., a predetermined region) OR of a mask assembly MSK contacting a substrate SUB in FIG. 2.

Referring to FIG. 1, the deposition device 100 may include a chamber CHB, a deposition member EP, a mask assembly MSKA, and a fixing member SCP.

The chamber CHB may provide an internal process region for performing a deposition process on a substrate SUB. An internal space of the chamber CHB may be a closed space, and, in an embodiment, a deposition condition of the deposition device 100 may be set to vacuum.

The deposition member EP, the fixing member SCP, and the mask assembly MSKA may be located in the internal space of the chamber CHB.

The fixing member SCP may face the deposition member EP in a third direction DR3 that is perpendicular to a first direction DR1 and a second direction DR2 that are parallel to a surface of the substrate SUB affixed by the fixing member SCP and on which a process is performed, in the internal space of the chamber CHB.

The mask assembly MSKA may include a mask frame MFR and a mask MSK attached to the mask frame MFR.

The fixing member SCP may support and fix the substrate SUB on which a deposition material is deposited under the mask assembly MSKA in the third direction DR3. In an embodiment, the fixing member SCP may include a jig or robot arm for holding the mask assembly MSKA. In an embodiment, the fixing member SCP may include magnetic materials for closely attaching the mask assembly MSKA and the substrate SUB. For example, the magnetic materials may generate a magnetic force to affix the mask assembly MSKA, and the substrate SUB between the mask assembly MSKA and the fixing member SCP may be closely attached to the mask assembly MSKA.

The deposition member EP may include a space in which a deposition material EM is received and at least one nozzle NZ. The deposition material EM may include an inorganic material or a metal, or an organic material sublimated or gasified. For example, the deposition material EM may include an organic material for forming layers included in the display panel.

The nozzle NZ may face the substrate SUB in the third direction DR3.

The deposition material EM may be sublimated or gasified and may be sprayed toward the substrate SUB through the nozzle NZ.

The deposition material EM may pass through the mask assembly MSKA and may be deposited on the substrate SUB.

The deposition device 100 in FIG. 1 shows a deposition process being performed by facing the substrate SUB and the deposition member EP in the third direction DR3 and depositing the deposition material on the substrate SUB in the third direction DR3, but embodiments are not limited thereto. The deposition process for facing the substrate SUB and the deposition member EP in the first direction DR1 or the second direction DR2 and depositing the deposition material on the substrate SUB in the first direction DR1 or the second direction DR2 may be performed, and the deposition material EM may pass through the mask assembly MSKA and may be deposited on the substrate SUB.

Although not shown in the drawings, in an embodiment, the deposition device 100 may further include a mechanical device for realizing an inline system.

In an embodiment, the deposition device 100 may further include a heat dissipating member located between the mask assembly MSKA and the deposition member EP. The heat dissipating member may include a material with high thermal conductivity. For example, the heat dissipating member may include a metal, such as aluminum or copper, an alloy thereof, carbon, or graphite. The heat dissipating member may absorb heat discharged from the deposition member EP and may prevent or substantially prevent the mask assembly MSKA from being deformed by heat during the deposition process.

Referring to FIG. 2, the mask assembly MSKA may include the mask frame MFR and the mask MSK. FIG. 2 shows the mask assembly MSKA as seen from above in the third direction DR3.

The mask MSK may be attached or connected to the mask frame MFR.

The mask MSK may include first mask bars MPBA and second mask bars MPBB defining opening regions DRA corresponding to the deposition region.

The first mask bars MPBA may be spaced apart from each other and may extend in the first direction DR1, and the second mask bars MPBB may be spaced apart from each other and may extend in the second direction DR2.

In an embodiment, each of the first mask bars MPBA may have a greater length than a length of each of the second mask bars MPBB.

The second mask bars MPBB may be located on the first mask bars MPBA in an overlapping region where the first mask bars MPBA overlap the second mask bars MPBB.

In an embodiment, thicknesses of the first mask bars MPBA may be substantially constant.

The first mask bars MPBA may be located below the second mask bars MPBB and may support the second mask bars MPBB.

In an embodiment, the first mask bars MPBA having a relatively great area overlapping the substrate SUB have a constant thickness, and a gap between the substrate SUB and the mask assembly MSKA depending on positions may not be great.

The mask frame MFR, the first mask bars MPBA, and the second mask bars MPBB may include one of metals with a very low thermal expansion coefficient according to changes of temperature, such as an Invar 36 alloy or stainless steel, but embodiments are not limited thereto.

The deposition material may be deposited on the substrate SUB through the opening regions DRA defined by the mask frame MFR, and the first mask bars MPBA and the second mask bars MPBB traversing each other.

Referring to FIG. 3 and FIG. 4 together with FIG. 1 and FIG. 2, each of the second mask bars MPBB of the mask assembly MSKA may include overlapping portions OLP overlapping and combining with the first mask bars MPBA and non-overlapping portions NOLP not overlapping the first mask bars MPBA. FIG. 3 shows a bottom surface of the mask assembly MSKA contacting the substrate SUB in a region (e.g., a predetermined region) OR in FIG. 2; and FIG. 4 shows a bottom surface of a second mask bar MPBB of the mask assembly MSKA.

In an embodiment, opposite end portions ED of each of the second mask bars MPBB may be coupled to the mask frame MFR. In an embodiment, opposite end portions of each of the first mask bars MPBA may be coupled to the mask frame MFR.

Each of the second mask bars MPBB may have combination grooves CPH in regions that correspond to the overlapping portions OLP. The combination grooves CPH may be at a bottom surface of each of the second mask bars MPBB in the third direction DR3.

The first mask bars MPBA may be inserted into the combination grooves CPH of the second mask bars MPBB, and the first mask bars MPBA may be coupled to the second mask bars MPBB.

In an embodiment, the first mask bars MPBA may have a substantially constant thickness in the overlapping portion OLP overlapping the second mask bars MPBB and other regions.

The non-overlapping portions NOLP of each of the second mask bars MPBB may include first portions NOLPA and a second portion NOLPB with different thicknesses.

Each of the second mask bars MPBB may have dummy grooves DMH in the second portion NOLPB of the non-overlapping portion NOLP.

The first portions NOLPA of the non-overlapping portion NOLP may be located at edges of opposite ends of the non-overlapping portion NOLP in a width direction of the non-overlapping portion NOLP and may face each other, and the second portion NOLPB of the non-overlapping portion NOLP may be located between the two first portions NOLPA located at edges of opposite ends.

The first portions NOLPA of the non-overlapping portion NOLP may extend in the second direction DR2 along the edge of the non-overlapping portion NOLP.

The thickness noted below may be measured in the third direction DR3 in which the substrate SUB overlaps the mask assembly MSKA.

Referring to FIG. 5 and FIG. 6, each of the second mask bars MPBB may have a first thickness T1 in the overlapping portion OLP, and the combination grooves CPH of each of the second mask bars MPBB may have a first depth D1. For example, the first thickness T1 of the overlapping portion OLP may be about 80 μm to about 120 μm, and, in an embodiment, about 90 μm to about 110 μm, and, in an embodiment, about 100 μm.

In an embodiment, the first depth D1 of the combination grooves CPH may be the same (equal or substantially equal) to the second thickness T2 of the first mask bar MPBA, but the embodiments are not limited thereto.

Referring to FIG. 7 together with FIG. 6, each of the non-overlapping portions NOLP of the second mask bars MPBB may include the first portions NOLPA and the second portion NOLPB with different thicknesses, and each of the second mask bars MPBB may have dummy grooves DMH that correspond to the second portions NOLPB of the non-overlapping portion NOLP.

In an embodiment, a third thickness T3 of the first portions NOLPA of the non-overlapping portion NOLP may be larger than a fourth thickness T4 of the second portion NOLPB.

The dummy grooves DMH may be located between the two first portions NOLPA located at opposite ends in the width direction of the non-overlapping portion NOLP, for example, the first direction DR1.

In an embodiment, a second depth D2 of the dummy grooves DMH may be the same (equal or substantially equal) to the first depth D1 of the combination grooves CPH, but embodiments are not limited thereto.

In an embodiment, the third thickness T3 of the first portions NOLPA of the non-overlapping portion NOLP may be a maximum thickness of the second mask bars MPBB, but embodiments are not limited thereto.

In an embodiment, the fourth thickness T4 of the second portions NOLPB of the non-overlapping portion NOLP may be the same (equal or substantially equal) to the first thickness T1 of the overlapping portion OLP, but embodiments are not limited thereto.

Referring to FIG. 4, the dummy groove DMH of the non-overlapping portion NOLP may extend in the second direction DR2 in which the second mask bar MPBB extends, and a length L1 of the non-overlapping portion NOLP and a length L2 of the dummy groove DMH may be the same (equal or substantially equal) to each other in the second direction DR2.

In an embodiment, one dummy groove DMH may be located in each non-overlapping portion NOLP.

According to an embodiment, each of the second mask bars MPBB may have combination grooves CPH that correspond to the overlapping portions OLP where second mask bars MPBB overlap and are coupled to the first mask bars MPBA. Each of the second mask bars MPBB may have the dummy grooves DMH that correspond to the non-overlapping portions NOLP not overlapping the first mask bars MPBA.

When each of the second mask bars MPBB has the combination grooves CPH that correspond to the overlapping portions OLP and have no dummy grooves DMH that correspond to the non-overlapping portions NOLP, the thickness difference of the second mask bars MPBB may be great in the overlapping portion OLP and the non-overlapping portion NOLP. When there is a thickness difference of the second mask bars MPBB depending on positions, the second mask bars MPBB may not be closely attached to the substrate SUB but may lift depending on positions during the process for manufacturing the mask assembly MSKA.

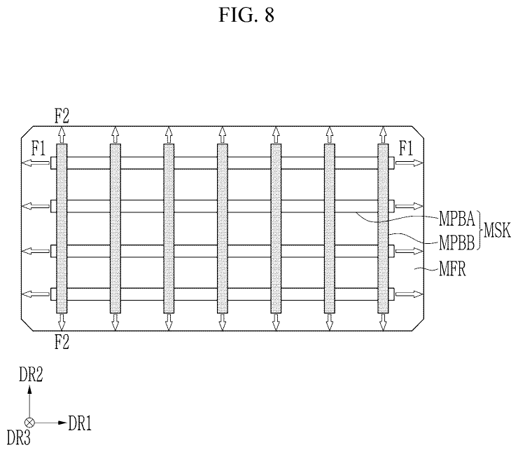

This will now be described with reference to FIG. 8. FIG. 8 shows a top plan view of a method for manufacturing a mask assembly according to an embodiment.

The first mask bars MPBA and the second mask bars MPBB may overlap each other and may be coupled to each other at the overlapping portions OLP and may be coupled to the mask frame MFR. To keep the surfaces of the first mask bars MPBA and the second mask bars MPBB flat, the first mask bars MPBA are pulled by applying first forces F1 to opposite ends of the first mask bars MPBA in a direction toward an outer edge of the mask frame MFR, and the second mask bars MPBB are pulled by applying second forces F2 to opposite ends of each of the second mask bars MPBB in a direction toward an outer edge of the mask frame MFR, and may be coupled to the mask frame MFR by a physical method, such as screw tightening or soldering, in a state in which the first forces F1 and the second forces F2 are applied. When the forces F1 and F2 are applied to the first mask bars MPBA and the second mask bars MPBB, and the thicknesses are different depending on the position, a density may become different depending on a position, and surfaces of the mask bars may not be planar and may have protrusions protruding upward or downward.

As described above, the thicknesses of the first mask bars MPBA may be substantially constant such that the surfaces of the first mask bars MPBA may not protrude by the first forces F1. However, the second mask bars MPBB may be located on the first mask bars MPBA in the overlapping portion OLP, and may have the combination grooves CPH in which the first mask bars MPBA are inserted to reduce the gap with the substrate SUB, and thus may have a thickness difference depending on a position. Therefore, the second mask bars MPBB may have protrusions protruding upward or downward by the second forces F2, and the second mask bar MPBB may be lifted without making close contact with the substrate SUB.

If a portion of the second mask bars MPBB lifts off from the mask MSK, the deposition material EM may be input to a gap thereof and may be transmitted to the substrate SUB. In this way, when the deposition material EM is input to the unnecessary positions, the deposition process may proceed in the unnecessary positions, and, accordingly, process accuracy may be reduced.

According to an embodiment of the present disclosure, each of the second mask bars MPBB may have dummy grooves DMH that correspond to the non-overlapping portions NOLP in addition to the combination grooves CPH that correspond to the overlapping portions OLP such that a thickness difference of the second mask bars MPBB in the overlapping portion OLP and the non-overlapping portion NOLP may be reduced. Therefore, the second mask bars MPBB may be prevented or substantially prevented from being lifted off and not being in close contact with the substrate SUB due to the thickness difference and density difference depending on the positions of the second mask bars MPBB, and the accuracy of the deposition process may be increased.

When the lift gap between the second mask bars MPBB and the mask MSK is equal to or less than about 10 μm, an inflow of the deposition material EM due to the lift gap may not be significant.

In an embodiment, a ratio W2/W1 of the second width W2 of one first portion NOLPA to the first width W1 of the second mask bar MPBB may be about 0.4, and, in an embodiment, about 0.1 to about 0.3, and when the ratio W2/W1 of the second width W2 to the first width W1 is equal to or less than about 0.4, and, in an embodiment, about 0.1 to about 0.3, the lift gap between the substrate SUB and the second mask bar MPBB may be equal to or less than about 10 μm.

According to an embodiment, each of the second mask bars MPBB has the dummy grooves DMH that correspond to the non-overlapping portions NOLP and the dummy grooves DMH are located at a central portion of the non-overlapping portions NOLP so as to be surrounded by the first portion NOLPA located along the edge of the non-overlapping portion NOLP. Accordingly, a periphery of each of the second mask bars MPBB may be in close contact with the substrate SUB with a narrow gap, thereby preventing or substantially preventing unnecessary deposition material EM from being input along the dummy grooves DMH.

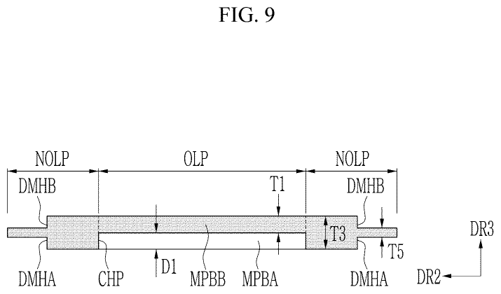

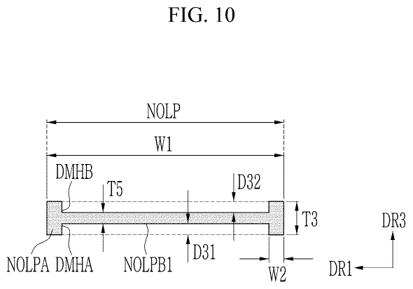

A deposition mask assembly according to another embodiment will now be described with reference to FIG. 9 and FIG. 10. FIG. 9 and FIG. 10 are each a cross-sectional view of a portion of a deposition mask according to another embodiment. FIG. 9 is a cross-sectional view along the line II-II′ of FIG. 3; and FIG. 10 is a cross-sectional view along the line III-III′ of FIG. 3.

Referring to FIG. 9 and FIG. 10, the overlapping portions OLP of each of the second mask bars MPBB of the deposition mask assembly according to the present embodiment are similar to the deposition mask assembly according to the above-described embodiment.

Each of the second mask bars MPBB may have the combination grooves CPH in the regions that correspond to the overlapping portions OLP. The combination grooves CPH may be at a bottom surface of each of the second mask bars MPBB in the third direction DR3.

Each of the second mask bars MPBB may have the combination grooves CPH in the regions that correspond to the overlapping portions OLP, the first mask bars MPBA may be inserted into the combination grooves CPH of the second mask bars MPBB to combine the first mask bars MPBA and the second mask bars MPBB such that the second mask bars MPBB may be supported by the first mask bars MPBA.

The non-overlapping portions NOLP of each of the second mask bars MPBB may include the first portion NOLPA and the second portion NOLPB with different thicknesses.

Each of the non-overlapping portions NOLP of the second mask bars MPBB of the deposition mask assembly may have a first dummy groove DMHA and a second dummy groove DMHB in a region that corresponds to the second portion NOLPB. The first dummy groove DMHA may be at a bottom surface of each of the second mask bars MPBB, and the second dummy groove DMHB may be at an upper surface of each of the second mask bars MPBB.

In an embodiment, the second portion NOLPB of the non-overlapping portion NOLP may have a fifth thickness T5, the fifth thickness T5 may be less than the third thickness T3 of the first portions NOLPA, and the fifth thickness T5 may be less than the first thickness T1 of the overlapping portion OLP. For example, the fifth thickness T5 of the second portion NOLPB of the non-overlapping portion NOLP may be about 30 μm to about 70 μm, and, in an embodiment, about 40 μm to about 60 μm, and, in an embodiment, about 50 μm.

In an embodiment, the ratio W2/W1 of the second width W2 of the first portion NOLPA to the first width W1 of the second mask bar MPBB may be about 0.4, and, in an embodiment, about 0.1 to about 0.3, and when the ratio W2/W1 of the second width W2 to the first width W1 is equal to or less than about 0.4, and, in an embodiment, about 0.1 to about 0.3, the lift gap between the mask MSK and the second mask bar MPBB may be equal to or less than about 10 μm.

According to an embodiment, each of the second mask bars MPBB have the first dummy grooves DMHA and the second dummy grooves DMHB that correspond to the non-overlapping portions NOLP in addition to the combination grooves CPH that correspond to the overlapping portions OLP such that the thickness difference of the second mask bars MPBB may be reduced in the overlapping portion OLP and the non-overlapping portion NOLP. Therefore, the second mask bars MPBB may be prevented or substantially prevented from being lifted off and not being in close contact with the substrate SUB due to the thickness difference and density difference occurring depending on the positions of the second mask bars MPBB, and the accuracy of the deposition process may be increased.

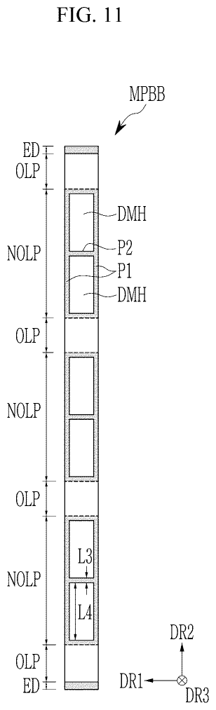

A mask assembly of a deposition device according to another embodiment will now be described with reference to FIG. 11. FIG. 11 is a top plan view of a portion of a mask assembly of a deposition device according to another embodiment.

Referring to FIG. 11, the mask assembly according to the present embodiment may be similar to the mask assemblies according to the above-described embodiments. Specific descriptions of the same components may be omitted.

The second mask bar MPBB of the mask assembly may include overlapping portions OLP overlapping and coupled to the first mask bar MPBA, non-overlapping portions NOLP not overlapping the first mask bars MPBA, and end portions ED coupled to the mask frame MFR.

Each of the second mask bars MPBB may have combination grooves CPH in the regions that correspond to the overlapping portions OLP.

Each of the non-overlapping portions NOLP of each of the second mask bars MPBB may include the first portion NOLPA and the second portion NOLPB with different thicknesses.

The fourth thickness T4 of the second portion NOLPB may be less than the third thickness T3 of the first portion NOLPA.

Each of the second mask bars MPBB may have dummy grooves DMH in the second portions NOLPB of the non-overlapping portions NOLP.

The third thickness T3 of the first portion NOLPA of the non-overlapping portion NOLP may be the maximum thickness of the second mask bars MPBB, but embodiments are not limited thereto.

According to one or more embodiments, the dummy grooves DMH in the second portions NOLPB of the non-overlapping portion NOLP may include a first dummy groove DMHA and a second dummy groove DMHB, but embodiments are not limited thereto.

According to one or more embodiments, the fourth thickness T4 of the second portion NOLPB of the non-overlapping portion NOLP may be the same (equal or substantially equal) to the first thickness T1 of the overlapping portion OLP, but embodiments are not limited thereto.

According to one or more embodiments, the fifth thickness T5 of the second portion NOLPB of the non-overlapping portion NOLP may be less than the first thickness T1 of the overlapping portion OLP, but embodiments are not limited thereto.

According to the mask assembly according to the present embodiment, the first portion NOLPA of the non-overlapping portion NOLP may include first sub-portions P1 extending in the second direction DR2 and spaced apart from each other in the first direction DR1 along the edge of the non-overlapping portion NOLP, and second sub-portions P2 extending in the first direction DR1 and connecting the first sub-portions P1 in opposite sides to each other.

The dummy grooves DMH that correspond to the second portion NOLPB of the non-overlapping portion NOLP may be located in the regions surrounded by the first sub-portions P1 and the second sub-portions P2 of the first portion NOLPA.

In an embodiment, a length L3 of the second sub-portion P2 of the first portion NOLPA may be less than a length L4 of the dummy grooves DMH in the second direction DR2.

The dummy grooves DMH spaced apart from each other in the second direction DR2 may be located at each of the non-overlapping portions NOLP.

According to an embodiment, each of the second mask bars MPBB may have the dummy grooves DMH that correspond to the non-overlapping portions NOLP in addition to the combination grooves CPH that correspond to the overlapping portions OLP such that the thickness difference of the second mask bars MPBB may be reduced in the overlapping portion OLP and the non-overlapping portion NOLP. Therefore, the second mask bars MPBB may be prevented or substantially prevented from being lifted off and not being in close contact with the substrate SUB due to a thickness difference and density difference that may occur depending on positions of the second mask bars MPBB, and the accuracy of the deposition process may be increased.

Characteristics of the mask assemblies and the deposition device according to the above-described embodiments may be applicable to the mask assembly according to the present embodiment.

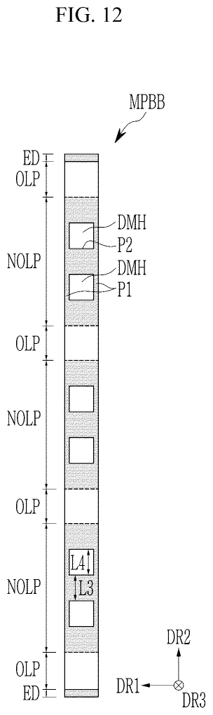

A mask assembly of a deposition device according to another embodiment will now be described with reference to FIG. 12. FIG. 12 is a top plan view of a portion of a mask assembly of a deposition device according to another embodiment.

Referring to FIG. 12, the mask assembly according to the present embodiment is similar to the mask assemblies according to the above-described embodiments. Detailed descriptions of the same components may be omitted.

The second mask bar MPBB of the mask assembly according to the present embodiment may include overlapping portions OLP overlapping and coupled to the first mask bar MPBA, non-overlapping portions NOLP not overlapping the first mask bars MPBA, and end portions ED coupled to the mask frame MFR.

Each of the second mask bars MPBB may have the combination grooves CPH formed in the regions that correspond to the overlapping portions OLP.

Each of the non-overlapping portions NOLP of each of the second mask bars MPBB may include a first portion NOLPA and a second portion NOLPB with different thicknesses.

In an embodiment, the fourth thickness T4 of the second portion NOLPB may be less than the third thickness T3 of the first portion NOLPA of the non-overlapping portion NOLP.

Each of the second mask bars MPBB may have the dummy grooves DMH formed on the second portion NOLPB of the non-overlapping portions NOLP.

In an embodiment, the third thickness T3 of the first portion NOLPA of the non-overlapping portion NOLP may be a maximum thickness of the second mask bars MPBB, but embodiments are not limited thereto.

According to one or more embodiments, the fourth thickness T4 of the second portion NOLPB of the non-overlapping portion NOLP may be the same (equal or substantially equal) to the first thickness T1 of the overlapping portion OLP, but embodiments are not limited thereto.

According to one or more embodiments, the fifth thickness T5 of the second portion NOLPB of the non-overlapping portion NOLP may be less than the first thickness T1 of the overlapping portion OLP, but embodiments are not limited thereto.

According to the mask assembly according to the present embodiment, the first portion NOLPA of the non-overlapping portion NOLP may include first sub-portions P1 extending in the second direction DR2 and spaced apart from each other in the first direction DR1 along the edge of the non-overlapping portion NOLP and second sub-portions P2 extending in the first direction DR1 and connecting the first sub-portions P1 located at opposite sides to each other.

The dummy grooves DMH that correspond to the second portion NOLPB of the non-overlapping portion NOLP may be located at the regions surrounded by the first sub-portions P1 and the second sub-portions P2 of the first portion NOLPA.

The dummy grooves DMH spaced apart from each other in the second direction DR2 may be located at each of the non-overlapping portion NOLP.

In an embodiment, the length L3 of the second sub-portion P2 of the first portion NOLPA may be the same (equal or substantially equal) to the length L4 of the dummy grooves DMH in the second direction DR2.

According to one or more embodiments, each of the second mask bars MPBB may have the dummy grooves DMH that correspond to the non-overlapping portions NOLP in addition to the combination grooves CPH that correspond to the overlapping portions OLP to thus reduce the thickness difference of the second mask bars MPBB in the overlapping portion OLP and the non-overlapping portion NOLP. Therefore, the second mask bars MPBB may be prevented or substantially prevented from being lifted off and not being in close contact with the substrate SUB due to the thickness difference and density difference that occurs depending on the positions of the second mask bars MPBB, and the mask MSK may be prevented or substantially prevented from being lifted off and not being in close contact with the substrate SUB, thereby the accuracy of the deposition process may be increased.

Characteristics of the mask assemblies and the deposition device according to the above-described embodiments may be applicable to the mask assembly according to the present embodiment.

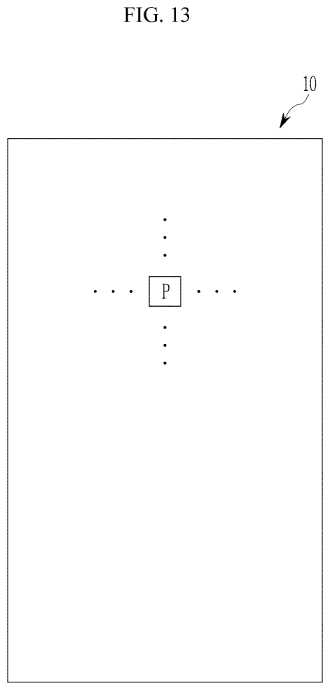

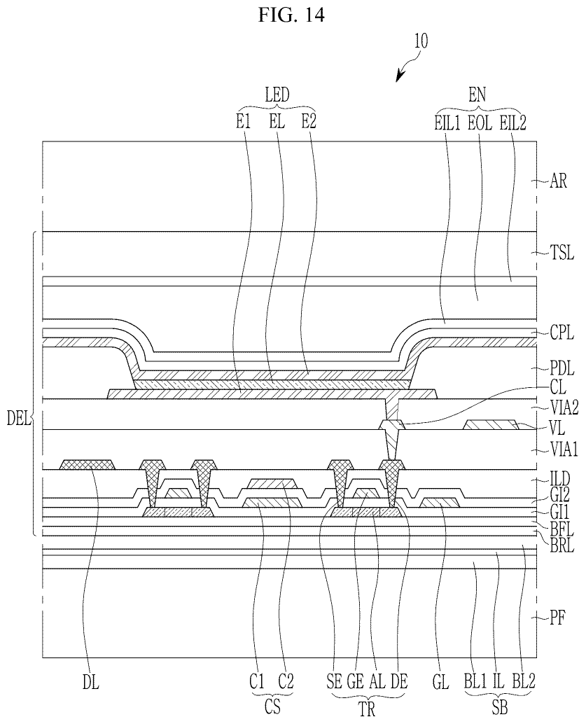

A display panel according to an embodiment will now be described with reference to FIG. 13 and FIG. 14. FIG. 13 is a top plan view of a display panel according to an embodiment; and FIG. 14 is a cross-sectional view of a display panel according to an embodiment.

At least some of the layers included in a display panel 1 described with reference to FIG. 13 and FIG. 14 may be formed using the mask assembly described with reference to FIG. 1 to FIG. 12 and the deposition device including the same by the deposition process.

Referring to FIG. 13, the display panel 1 may include pixels P. A cross-section shown in FIG. 14 may substantially correspond to a pixel P region.

Referring to FIG. 13 and FIG. 14, the display panel 1 may include a substrate SB, a transistor TR formed on the substrate SB, and a light emitting diode LED connected to the transistor TR. The light emitting diode LED may correspond to the pixel.

In an embodiment, the substrate SB may be a multilayer substrate including a first base layer BL1, an inorganic layer IL, and a second base layer BL2. The first and second base layers BL1 and BL2 may include a polymer resin, such as polyimide, polyamide, or polyethylene terephthalate.

A barrier layer BRL for preventing or substantially preventing permeation of moisture or oxygen may be located on the substrate SB. In an embodiment, the barrier layer BRL may include an inorganic insulating material, such as silicon nitride (SiNₓ), silicon oxide (SiOₓ), or silicon oxynitride (SiOₓN_{y}), and may be a single layer or a multilayer.

A buffer layer BFL may be located on the barrier layer BRL. The buffer layer BFL may increase characteristics of the semiconductor layer by blocking impurities from the substrate SB when forming the semiconductor layer, and may relieve a stress of the semiconductor layer by planarizing the surface of the substrate SB. In an embodiment, the buffer layer BFL may include an inorganic insulating material, such as silicon nitride, silicon oxide, or silicon oxynitride, and may be a single layer or a multilayer. In an embodiment, the buffer layer BFL may include amorphous silicon (Si).

A semiconductor layer AL of the transistor TR may be located on the buffer layer BFL. The semiconductor layer AL may include a first region and a second region, and a channel region between the first and second regions. The semiconductor layer AL may include one of amorphous silicon, polycrystalline silicon, and an oxide semiconductor. For example, the semiconductor layer AL may include low-temperature polycrystalline silicon (LTPS), or may include an oxide semiconductor material including at least one of zinc (Zn), indium (In), gallium (Ga), and tin (Sn). For example, the semiconductor layer AL may include indium-gallium-zinc oxide (IGZO).

A first gate insulating layer GI1 may be located on the semiconductor layer AL. The first gate insulating layer GI1 may include an inorganic insulating material, such as silicon nitride, silicon oxide, or silicon oxynitride, and may be a single layer or a multilayer.

A first gate conductive layer including a gate electrode GE of the transistor TR, a gate line GL, and a first electrode C1 of a capacitor CS may be located on the first gate insulating layer GI1. In an embodiment, the first gate conductive layer may include molybdenum (Mo), aluminum (Al), copper (Cu), and titanium (Ti), and may be a single layer or a multilayer.

A second gate insulating layer GI2 may be located on the first gate conductive layer. The second gate insulating layer GI2 may include an inorganic insulating material, such as silicon nitride, silicon oxide, or silicon oxynitride, and may be a single layer or a multilayer.

A second gate conductive layer including a second electrode C2 of the capacitor CS may be located on the second gate insulating layer GI2. In an embodiment, the second gate conductive layer may include molybdenum (Mo), aluminum (Al), copper (Cu), and titanium (Ti), and may be a single layer or a multilayer.

An interlayer insulating layer ILD may be located on the second gate insulating layer GI2 and the second gate conductive layer. The interlayer insulating layer ILD may include an inorganic insulating material, such as silicon nitride, silicon oxide, or silicon oxynitride, and may be a single layer or a multilayer.

A first data conductive layer including a first electrode SE and a second electrode DE of the transistor TR and a data line DL may be located on the interlayer insulating layer ILD. The first electrode SE and the second electrode DE may be connected to the first region and second region of the semiconductor layer AL through contact holes of the insulating layers GI1, GI2, and ILD. One of the first electrode SE and the second electrode DE may be a source electrode and the other thereof may be a drain electrode. In an embodiment, the first data conductive layer may include any of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer.

A first planarization layer VIA1 may be located on the first data conductive layer. The first planarization layer VIA1 may be an organic insulator. For example, the first planarization layer VIA1 may include an organic insulating material, such as any of a general-purpose polymer, such as polymethyl methacrylate or polystyrene, a polymer derivative having a phenol-based group, an acryl-based polymer, an imide-based polymer, polyimide, an acryl-based polymer, and a siloxane-based polymer.

A second data conductive layer including a voltage line VL and a connection line CL may be located on the first planarization layer VIA1. The voltage line VL may transmit a voltage, such as any of a driving voltage, a common voltage, an initialization voltage, and a reference voltage. The connection line CL may be connected to the second electrode DE of the transistor TR through the contact hole of the first planarization layer VIA1. In an embodiment, the second data conductive layer may include any of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or a multilayer.

A second planarization layer VIA2 may be located on the second data conductive layer. The second planarization layer VIA2 may be an organic insulator. For example, the second planarization layer VIA2 may include an organic insulating material, such as any of a general-purpose polymer, such as polymethyl methacrylate or polystyrene, a polymer derivative having a phenol-based group, an acryl-based polymer, an imide-based polymer, polyimide, an acryl-based polymer, and a siloxane-based polymer.

A first electrode E1 of the light emitting diode LED may be located on the second planarization layer VIA2. The first electrode E1 may be referred to as a pixel electrode. The first electrode E1 may be connected to the connection line CL through the contact hole of the second planarization layer VIA2. Therefore, the first electrode E1 may be electrically connected to the second electrode DE of the transistor TR and may receive a data signal for controlling luminance of the light emitting diode. The transistor TR connected to the first electrode E1 may be a driving transistor or a transistor electrically connected to the driving transistor. The first electrode E1 may be made of a reflective conductive material or a semi-transmissive conductive material, and may be made of a transparent conductive material. The first electrode E1 may include the transparent conductive material, such as indium tin oxide (ITO) or indium zinc oxide (IZO). The first electrode E1 may include a metal, such as lithium (Li), calcium (Ca), aluminum (Al), silver (Ag), magnesium (Mg), or gold (Au), or metal alloys thereof.

A pixel defining layer PDL that may be an organic insulator may be located on the second planarization layer VIA2. The pixel defining layer PDL may be referred to as a barrier rib and may have an opening overlapping the first electrode E1.

A light emitting layer EL of the light emitting diode LED may be located on the first electrode E1. At least one of the hole injection layer, the hole transport layer, the electron transport layer, and the electron injection layer may be located on the first electrode E1 in addition to the light emitting layer EL.

A second electrode E2 of the light emitting diode LED may be located on the light emitting layer EL. The second electrode E2 may be referred to as a common electrode. The second electrode E2 may be formed to have a thin layer using metal with a low work function, such as calcium (Ca), barium (Ba), magnesium (Mg), aluminum (Al), or silver (Ag), or metal alloys thereof to be light-transmissive. The second electrode E2 may include a transparent conductive oxide, such as indium tin oxide (ITO) or indium zinc oxide (IZO).

The first electrode E1, the light emitting layer EL, and the second electrode E2 of each pixel may form the light emitting diode LED, such as an organic light emitting diode. The first electrode E1 may be an anode of the light emitting diode, and the second electrode E2 may be a cathode of the light emitting diode.

A capping layer CPL may be located on the second electrode E2. The capping layer CPL may increase light efficiency by adjusting a refractive index. The capping layer CPL may be located to cover the second electrode E2. The capping layer CPL, in an embodiment, may include an organic insulating material, and, in an embodiment, may include an inorganic insulating material.

An encapsulation layer EN may be located on the capping layer CPL. The encapsulation layer EN may encapsulate the light emitting diode LED to prevent or substantially prevent moisture or oxygen from permeating from the outside. The encapsulation layer EN may be a thin encapsulation layer including at least one of inorganic layers EIL1 and EIL2 and at least one organic layer EOL.

A touch sensor layer TSL including touch electrodes may be located on the encapsulation layer EN. In an embodiment, the touch electrodes may have a mesh shape having an opening overlapping the light emitting diode LED. An antireflection layer AR for reducing reflection of external light may be located on the touch sensor layer TSL.

A display element layer DEL may include layers located between the substrate SB and the antireflection layer AR, and may include the transistor TR, the capacitor CS, and the light emitting diode LED.

In an embodiment, a protection film PF for protecting the display panel 10 may be located below the substrate SUB. In an embodiment, a functional sheet (not shown) including at least one of a cushion layer, a heat radiation sheet, a light blocking sheet, a watertight tape, and an electromagnetic blocking film may be located below the protection film.

The display device according to one or more embodiments may be applied to any of various electronic devices. An electronic device according to an embodiment may include the display device, and may further include modules or devices having additional functions other than the display device.

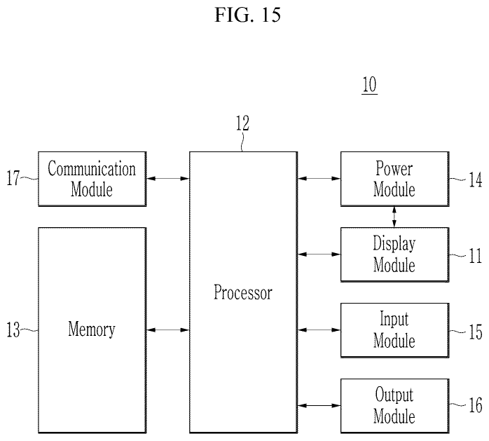

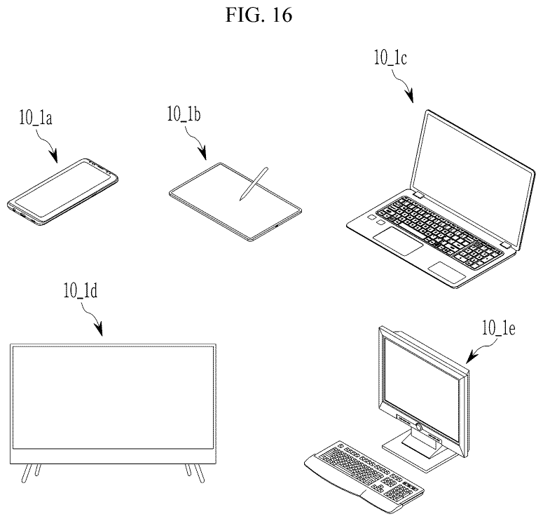

Referring to FIG. 15 to FIG. 18, an electronic device according to one or more embodiments will be described. FIG. 15 is a block diagram of an electronic device according to an embodiment; and FIGS. 16 to 18 are schematic views of electronic devices according to some embodiments.

Referring to FIG. 15, an electronic device 10 according to an embodiment may include a display module 11, a processor 12, a memory 13, and a power module 14. The electronic device 10 may further include an input module 15, a non-visual, or non-image, output module 16, and/or a communication module 17.

The electronic device 10 may output various information in the form of images through the display module 11. When the processor 12 executes an application stored in the memory 13, image information provided by the application may be provided to a user through the display module 11. The power module 14 may include a power supply module, such as a power adapter or a battery device, and a power conversion module that converts power supplied by the power supply module to generate power necessary for operation of the electronic device 10. The input module 15 may provide input information to the processor 12 and/or the display module 11. The non-image output module 16 may receive non-image information from the processor 12, for example, sound, haptic, or light information, and provide the information to a user. The communication module 17 is a module responsible for transmitting and receiving information between the electronic device 10 and external devices, and may include a receiver and a transmitter.

At least one of the components of the above-described electronic device 10 may be included in the display device according to the above-described embodiments. Also, some of the individual modules that are functionally included in one module may be included in the display device, and other parts may be provided separately from the display device. For example, the display device may include the display module 11, and the processor 12, memory 13, and power module 14 may be provided in the form of other devices within the electronic device 10 that is not the display device.

FIGS. 16 to 18 illustrate some examples of electronic devices to which the display device according to the embodiments may be applied.

FIG. 16 illustrates a smartphone 10_1a, a tablet PC 10_1b, a laptop 10_1c, a TV 10_1d, and a desktop monitor 10_1e as some examples of electronic devices.

The smartphone 10_1a may include an input module, such as a touch sensor and a communication module, in addition to the display module 11. The smartphone 10_1a may process information received through the communication module or other input modules to display information through the display module of the display device.

The tablet PC 10_1b, the laptop 10_1c, the TV 10_1d, and the desktop monitor 10_1e may include a display module and an input module similar to the smartphone 10_1a, and may further include a communication module in one or more embodiments.

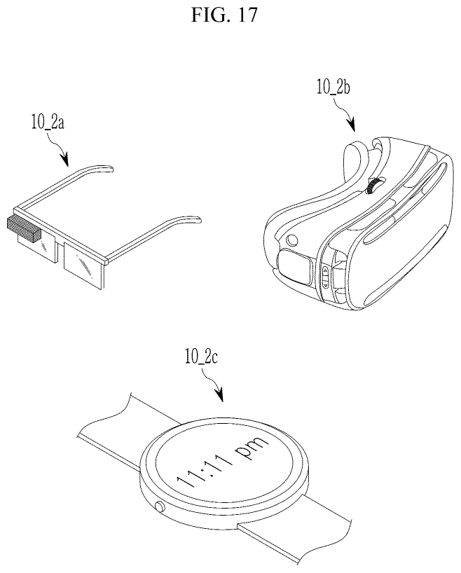

FIG. 17 illustrates a case in which an electronic device including a display module is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display module that emits display images and a reflector that reflects the emitted display screen to provide to a user's eyes, and, through this, may provide virtual reality or augmented reality screens to the user.

The smart watch 10_2c may include a biosensor as an input device, and can provide biometric information recognized through the biosensor to a user through the display module.

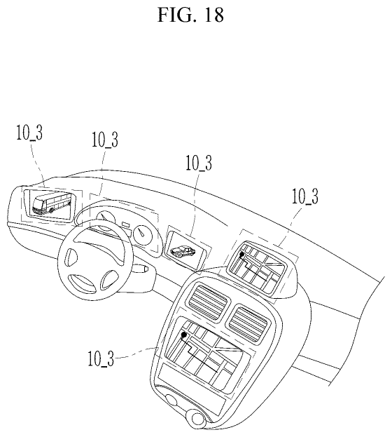

FIG. 18 illustrates a case in which an electronic device including a display module is applied to a vehicle. For example, the electronic device 10_3 may be applied to a vehicle instrument panel, a center fascia, or may be applied to a CID (Center Information Display) placed on a vehicle dashboard or a room mirror display replacing a side mirror.

While the present disclosure has been described in connection with what are presently considered to be some practical embodiments, it is to be understood that the disclosure is not limited to the disclosed embodiments, but, on the contrary, is intended to cover various modifications and equivalent arrangements included within the spirit and scope of the appended claims.

What is claimed is:

1. A mask assembly comprising:
a mask frame;
a first mask bar connected to the mask frame and extending in a first direction; and
a second mask bar connected to the mask frame and extending in a second direction,
wherein the first mask bar overlaps the second mask bar in an overlapping region,
the second mask bar comprises a non-overlapping region not overlapping the first mask bar,
the second mask bar comprises a first portion having a first thickness, and a second portion having a second thickness that is less than the first thickness in the non-overlapping region, and
the first portion is located along an edge of the second mask bar.

2. The mask assembly of claim 1, wherein
the first portion comprises two first sub-portions located at edges at opposite sides of the second mask bar in the first direction and spaced apart from each other, and
the second portion is between the two first sub-portions.

3. The mask assembly of claim 2, wherein the second mask bar comprises a dummy groove corresponding to the second portion.

4. The mask assembly of claim 3, wherein
the second mask bar is located on the first mask bar in the overlapping region, and
the dummy groove is at a bottom surface of the second mask bar.

5. The mask assembly of claim 3, wherein
the second mask bar is located on the first mask bar in the overlapping region, and
the dummy groove comprises a first dummy groove at a bottom surface of the second mask bar and a second dummy groove at an upper surface of the second mask bar.

6. The mask assembly of claim 3, wherein the second mask bar comprises a combination groove corresponding to the overlapping region.

7. The mask assembly of claim 6, wherein a depth of the dummy groove is the same as a depth of the combination groove.

8. The mask assembly of claim 2, wherein
the first sub-portions extend in a direction parallel to the second direction,
the second portion extends in a direction parallel to the second direction, and
a length of the second portion is the same as a length of the non-overlapping region in a direction parallel to the second direction.

9. The mask assembly of claim 8, wherein
the first portion further comprises second sub-portions extending in the second direction and connecting the first sub-portions, and
the dummy groove comprises grooves surrounded by the first sub-portions and the second sub-portions.

10. The mask assembly of claim 9, wherein a length of each of the second sub-portions is less than a length of the dummy groove in the second direction.

11. The mask assembly of claim 9, wherein a length of each of the second sub-portions is the same as a length of the dummy groove in the second direction.

12. A deposition device comprising:
a chamber providing a process region;
a deposition member and a fixing member facing each other in the chamber; and
a mask assembly between the deposition member and the fixing member,
wherein a substrate to be processed is arrangeable between the fixing member and the mask assembly,
the mask assembly comprises a mask frame, a first mask bar connected to the mask frame and extending in the first direction, and a second mask bar connected to the mask frame and extending in the second direction,
the first mask bar overlaps the second mask bar in the overlapping region,
the second mask bar comprises a non-overlapping region not overlapping the first mask bar,
the second mask bar comprises a first portion having a first thickness and a second portion having a second thickness that is less than the first thickness in the non-overlapping region, and
the first portion is located along an edge of the second mask bar.

13. The deposition device of claim 12, wherein
the first portion comprises two first sub-portions located along edges at opposite sides of the second mask bar in the first direction, and
the second portion is located between the two first sub-portions.

14. The deposition device of claim 13, wherein the second mask bar comprises a combination groove corresponding to the overlapping region and a dummy groove corresponding to the second portion.

15. The deposition device of claim 14, wherein
the second mask bar is located on the first mask bar in the overlapping region, and
the dummy groove is at a bottom surface of the second mask bar.

16. The deposition device of claim 14, wherein
the second mask bar is located on the first mask bar in the overlapping region, and
the dummy groove comprises a first dummy groove at a bottom surface of the second mask bar, and a second dummy groove at an upper surface of the second mask bar.

17. The deposition device of claim 14, wherein a depth of the dummy groove is the same as a depth of the combination groove.

18. The deposition device of claim 13, wherein
the first sub-portions extend in a direction parallel to the second direction,
the second portion extends in a direction parallel to the second direction, and
a length of the second portion is the same as a length of the non-overlapping region in a direction parallel to the second direction.

19. The deposition device of claim 18, wherein
the first portion further comprises second sub-portions extending in the second direction and connecting the first sub-portions, and
the dummy groove comprises grooves surrounded by the first sub-portions and the second sub-portions.

20. The deposition device of claim 19, wherein a length of each of the second sub-portions is less than a length of the dummy groove in the second direction.
